(19) United States
(12) Patent Application Publication
(10) Pub. No.: US 2024/0047570 A1
(43) Pub. Date: Feb. 8, 2024

(54) POWER SEMICONDUCTOR DEVICE AND MANUFACTURING METHOD THEREOF

(71) Applicant: Magnachip Semiconductor, Ltd., Cheongju-si (KR)

(72) Inventors: Chanho PARK, Seoul (KR); Hohyun KIM, Seoul (KR); Youngseok KIM, Yongin-si (KR); Taehyun OH, Seoul (KR)

(73) Assignee: Magnachip Semiconductor, Ltd., Cheongju-si (KR)

(21) Appl. No.: 18/110,015

(22) Filed: Feb. 15, 2023

(30) Foreign Application Priority Data
Aug. 3, 2022 (KR) 10-2022-0096756

(51) Int. Cl. H01L 29/78; H01L 29/66; H01L 29/423; H01L 29/06

(52) U.S. Cl. CPC H01L 29/7813; H01L 29/66734; H01L 29/4236; H01L 29/0615

(57) ABSTRACT

A power semiconductor device includes: a drain electrode; a first conductive substrate disposed on the drain electrode; a first conductive epitaxial layer disposed on the first conductive substrate; a first conductive drift layer formed within the first conductive epitaxial layer; trenches formed in the first conductive epitaxial layer; a shield electrode formed in a lower portion of each trench; a shield oxide layer formed within each trench and formed to surround the shield electrode; a gate electrode formed within each trench and formed on the shield electrode; a second conductive body region formed on an upper portion comprising a surface of the first conductive epitaxial layer between the plurality of trenches; a source region formed on the second conductive body region; an insulation layer formed on the gate electrode; a source contact layer formed in contact with the source region; and a source electrode formed on the source contact layer.

### CROSS-REFERENCE TO RELATED APPLICATIONS

The present application claims the benefit under 35 U.S.C. 119(a) of Korea Patent Application No. 10-2022-0096756, filed Aug. 3, 2022, the entire disclosure of which is incorporated herein by reference for all purposes.

### BACKGROUND

### 1. Field

The following description relates to a power semiconductor device and a manufacturing method thereof and particularly to a power semiconductor device in which an ultra-short channel is implemented, and a manufacturing method thereof.

### 2. Description of the Related Art

A power semiconductor device operates in a wide operating voltage range, and the operating voltage range is typically between 10 V and 1,500 V.

In particular, a low voltage power MOSFET device of 30 V or less is applied to various applications such as a battery protection circuit, a PC main board, an inverter, and a converter, etc. It is important to obtain a low on-resistance (low Rdson) value between a drain and a source during electrical connection or during the operation of the device while maintaining a breakdown voltage.

The power MOSFET device is an ON-OFF switching device and has important characteristics of on-resistance during ON operation and breakdown voltage during OFF operation. The breakdown voltage and the on-resistance characteristics have a trade-off relationship with each other.

Previously, the breakdown voltage could be easily obtained by forming a thick epitaxial layer on a semiconductor substrate and forming a long drift region. However, due to the thick epitaxial layer, a low on-resistance during current conduction or during the operation of the device could not be obtained. In particular, in a trench power MOSFET device, while the breakdown voltage can be increased by increasing the thickness of the epitaxial layer, on-resistance increases due to a trade-off, thereby increasing power consumption.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. According to one or more embodiments of the present disclosure, an ultra-short channel may be implemented by minimizing the trench depth and the thickness of the epitaxial layer and optimizing thermal treatment conditions, thereby minimizing a resistance of the channel and a resistance of the epitaxial layer. Accordingly, it is possible to provide a semiconductor device having a remarkably low on-resistance without the reduction of the breakdown voltage, and a method for manufacturing the same.

In one general aspect, a semiconductor device including: a drain electrode; a first conductive substrate disposed on the drain electrode; a first conductive epitaxial layer disposed on the first conductive substrate; a first conductive drift layer formed within the first conductive epitaxial layer; a plurality of trenches formed in the first conductive epitaxial layer; a shield electrode formed in a lower portion of each of the plurality of trenches; a shield oxide layer formed within each of the plurality of trenches and formed to surround the shield electrode; a gate electrode formed within each of the plurality of trenches and formed on the shield electrode; a second conductive body region formed on an upper portion comprising a surface of the first conductive epitaxial layer between the plurality of trenches; a source region formed on the second conductive body region; an insulation layer formed on the gate electrode; a source contact layer formed in contact with the source region; and a source electrode formed on the source contact layer.

In another general aspect, a method for manufacturing a semiconductor device includes: forming a first conductive epitaxial layer on a first conductive semiconductor substrate; forming a plurality of trenches in the first conductive epitaxial layer; forming a sacrificial oxide layer on a surface of the plurality of trenches; removing the sacrificial oxide layer; forming a shield oxide layer on surfaces of the plurality of trenches and the first conductive epitaxial layer; forming a shield electrode in a lower portion of each of the plurality of trenches; depositing a gate oxide layer on surfaces of the plurality of trenches, the shield oxide layer and the first conductive epitaxial layer; forming a gate electrode on the shield electrode; forming a second conductive body region on an upper portion comprising a surface of the first conductive epitaxial layer between the plurality of trenches; forming a source region on the second conductive body region; forming an insulation layer on the gate electrode; forming a source contact layer in contact with the source region; forming a source electrode on the source contact layer; and forming a drain electrode under the semiconductor substrate. Other features and aspects will be apparent from the following detailed description, the drawings and the claims.

### BRIEF DESCRIPTION OF THE DRAWINGS

FIG. 1A illustrates a stacked structure of a semiconductor device according to one or more embodiments of the present disclosure;

FIG. 1B illustrates an electric field of a depletion layer region in the stacked structure of the semiconductor device, according to one or more embodiments of the present disclosure;

FIG. 1C illustrates an enlarged view of a part of FIG. 1A;

FIG. 2A illustrates a comparison between the present disclosure and a conventional technology in a doping profile according to a depth of a side area of a trench;

FIG. 2B illustrates a comparison between the present disclosure and a conventional technology in an enlarged doping profile of a body region of the trench side area;

FIG. 3 illustrates a process flowchart for describing a manufacturing method of the semiconductor device; and

FIGS. 4A to 4L illustrate views for describing the manufacturing method of the semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items. Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. Due to manufacturing techniques and/or tolerances, variations of the shapes shown in the drawings may occur. Thus, the examples described herein are not limited to the specific shapes shown in the drawings, but include changes in shape that occur during manufacturing. The features of the examples described herein may be combined in various ways as will be apparent after an understanding of the disclosure of this application. Further, although the examples described herein have a variety of configurations, other configurations are possible as will be apparent after an understanding of the disclosure of this application.

A breakdown voltage of a semiconductor device may be determined by distribution and area of the electric field (E-Field) of a P-body region and an N-drift region formed between trench MOSFETs and by a width of a depletion layer.

When the thickness of the epitaxial layer is increased, the width of the depletion layer formed in the P-body region and the N-drift region is increased to not only increase the breakdown voltage of the semiconductor device but also increase the on-resistance. Accordingly, conduction power loss in an on-state may increase. To solve this, the reduction of the thickness of the epitaxial layer can reduce the on-resistance of the semiconductor device. However, the breakdown voltage can also be reduced, so that desired device characteristics may not be obtained.

If a suitable breakdown voltage is not implemented, the device may be damaged due to a high reverse voltage generated by switching-off of the semiconductor device.

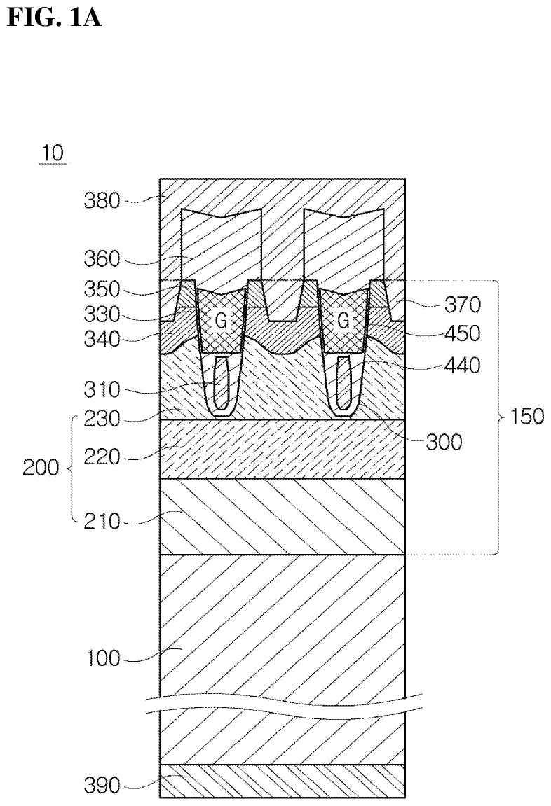

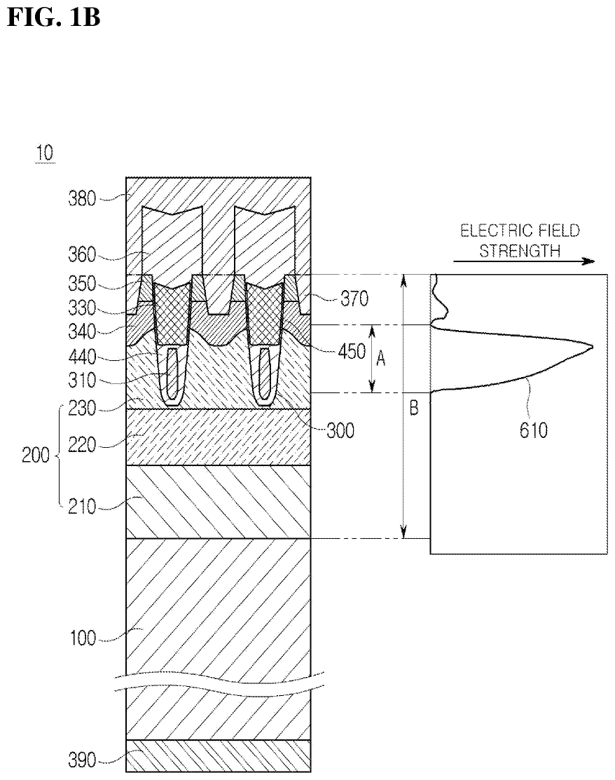

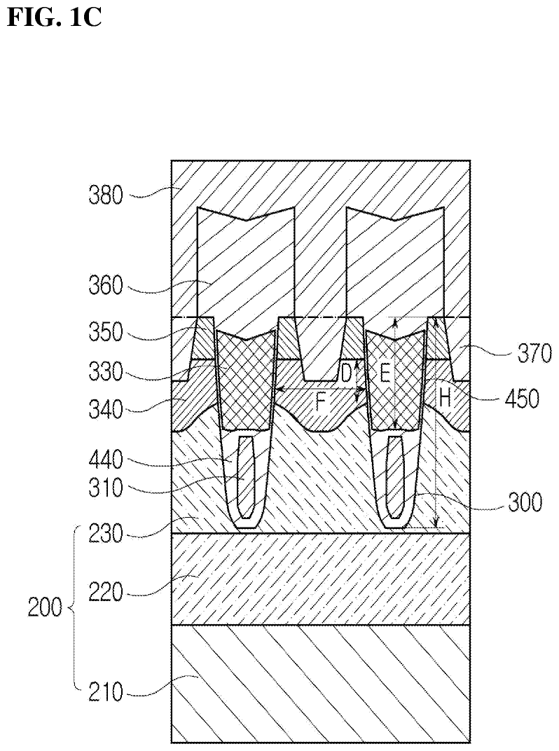

FIG. 1A illustrates a stacked structure of the semiconductor device according to one or more embodiments of the present disclosure. In an example, the semiconductor device shown in FIG. 1A may be a power MOSFET device, and in particular, a power switching device. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

Referring to FIG. 1A, the semiconductor device 10 may include a drain electrode 390, a first conductive semiconductor substrate 100 disposed on the drain electrode 390, a first conductive epitaxial layer 150 disposed on the first conductive semiconductor substrate 100, a plurality of trenches 300 formed in the first conductive epitaxial layer 150, a shield electrode 310 formed in a lower portion of each of the plurality of trenches 300, a shield oxide layer 440 formed within each of the plurality of trenches 300 and formed to surround the shield electrode 310, a gate electrode 330 formed in each of the plurality of trenches 300 and formed on the shield electrode 310 and the shield oxide layer 440, a second conductive body region 340 formed on an upper portion including a surface of the first conductive epitaxial layer 150 between the plurality of trenches 300, a source region 350 formed on the second conductive body region 340, an insulation layer 360 formed on the gate electrode 330, a gate oxide layer 450 formed on a side of the gate electrode, and the source region 350, a source contact layer 370 formed in contact with the source region 350, and a source electrode 380 formed on the source contact layer 370.

Also, according to one or more embodiments, a trench power MOSFET device may be formed with a single gate polysilicon structure. That is, only the gate electrode may be formed in a single polysilicon structure without forming the shield electrode 310 within the trench 300. In this case, a thick oxide layer may be formed under the single polysilicon.

In an example, the epitaxial layer 150 may be formed by growing an epitaxial layer on the semiconductor substrate 100 doped with an ultra-high concentration first conductive dopant, and the ultra-high concentration first conductive dopant doped on the semiconductor substrate 100 may be out-diffused into the epitaxial layer due to a thermal treatment which is performed in a subsequent step. Accordingly, high concentration, medium concentration, and low concentration dopant layers may be formed within the first conductive epitaxial layer 150.

For this reason, the epitaxial layer 150 may include a drift layer 200. Also, the drift layer 200 may include a high concentration drift layer 210, a medium concentration drift layer 220, and a low concentration drift layer 230.

The depths of the high concentration drift layer 210, the medium concentration drift layer 220, and the low concentration drift layer 230 may be different from each other. The high concentration drift layer 210 is disposed between the ultra-high concentration semiconductor substrate 100 and the medium concentration drift layer 220. The medium concentration drift layer 220 is disposed between the high concentration drift layer 210 and the bottom of the shield electrode 310 or the bottom of the trench 300. In order to realize a low on-resistance, the upper surface of the medium concentration drift layer 220 may be out-diffused into the lower surface of the trench or may partially overlap the lower surface of the trench. The low concentration drift layer 230 is disposed between the medium concentration drift layer 220 and the second conductive body region 340. The low concentration drift layer 230 is disposed between the plurality of trenches 300.

In addition, as described above, by considering the difference in the dopant concentrations in each drift layer, the high concentration drift layer 210 may be denoted by N+ region, the medium concentration drift layer 220 may be denoted by N region, and the low concentration drift layer 230 may be denoted by N− region.

FIG. 1B illustrates an electric field (E-field) of a depletion layer region in the stacked structure of the semiconductor device, according to one or more embodiments of the present disclosure.

The electric field (E-field) 610 of FIG. 1B is shown as a graph that illustrates the electric field 610 of the depletion layer between the body region and the drift layer. The breakdown voltage of the semiconductor device may be determined by the integral value of the electric field strength. In comparison to a conventional art, despite the fact that a depth “B” of the epitaxial layer, that is, a depth of the drift layer is reduced, a depth “A” of the depletion layer and the corresponding electric field (E-field) strength can be maintained the same, and the same breakdown voltage can be obtained. When the semiconductor device is turned on and off, it is possible to obtain a stable breakdown voltage, thereby preventing device damage due to the generation of a reverse voltage.

In an example, a ratio of the depth “A” of the depletion layer to the depth “B” of the epitaxial layer 150 may be 1:4 to 1:8.

Referring to FIGS. 1A and 1B, the depth of the trench 300 may be formed between 0.5 μm and 6 μm. Also, the depth of the trench 300 may be formed between 0.3 and 0.9 times the depth “B” of the epitaxial layer 150. This results in thin epitaxial layer and trenches. Since the resistivity of the epitaxial layer decreases with the thickness of the epitaxial layer, a lower on-resistance (Low Rdson) can be obtained.

According to one or more embodiments of the present disclosure, the upper surface of the gate electrode 330 may be lower than the upper surface of the first conductive epitaxial layer 150. In an example, the upper surface of the gate electrode 330 may be positioned about 60 nm to 120 nm lower than the upper surface of the first conductive epitaxial layer 150.

Referring to FIG. 1C according to one or more embodiments of the present disclosure, a depth “D” of a portion where a side surface of the second conductive body region 340 and the gate oxide layer 450 are adjacent to each other may be equal to or less than ½ of a depth “E” from the upper surface of the first conductive epitaxial layer 150 to the lower surface of the gate electrode 330. In addition, the depth “D” of the second conductive body region may be a channel length defined in the present disclosure.

In an example, the maximum width “F” of the second conductive body region 340 may be in a range of ½ to 1/20 of the depth “H” of the trench 300.

In an example, a ratio of the depth “D” of the second conductive body region to the depth “H” of the trench may be in a range of 1:2 to 1:30.

In an example, the source contact layer 370 may be provided to simultaneously contact the body region 340 and the source region 350.

In an example, in a trench power MOSFET device made of single gate polysilicon, the gate oxide layer may be formed on a side surface of the single polysilicon gate electrode.

In an example, the side surface of the body region 340 comes into contact with the gate oxide layer 450, and a center of the body region 340 comes into contact with the source contact layer 370. A central portion of the body region 340 may be disposed lower than the side portion of the body region 340 in a direction of the low concentration drift layer 230.

In an example, a doping concentration of the dopant of the epitaxial layer 150 may gradually decrease toward the body region 340 from the contact surface with the semiconductor substrate 100.

In an example, the semiconductor device 10 may be formed in a trench power MOSFET structure made of a single polysilicon. In this case, the semiconductor device 10 may be formed in the trench power MOSFET structure including only a gate electrode made of a single polysilicon without forming a separate shield electrode 310.

In an example, the shield electrode 310 and the gate electrode 330 may be formed deeper by making the trench 300 deeper.

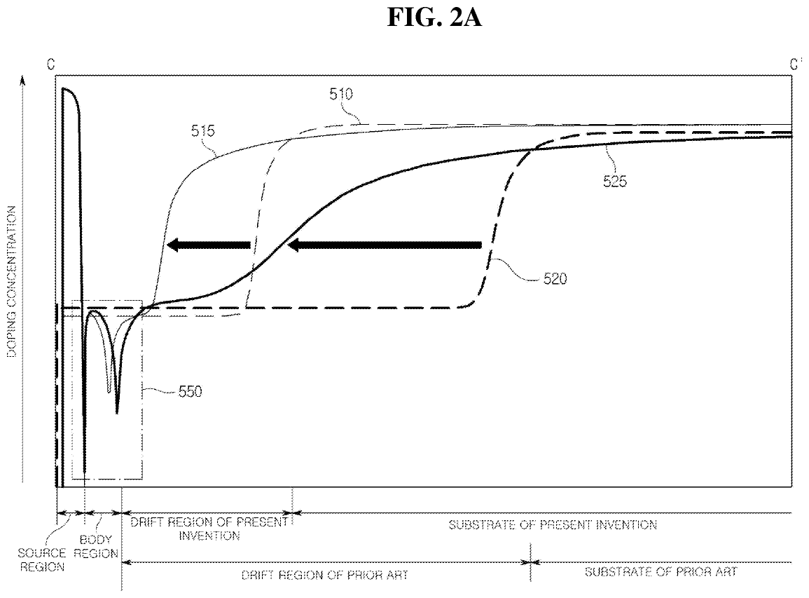

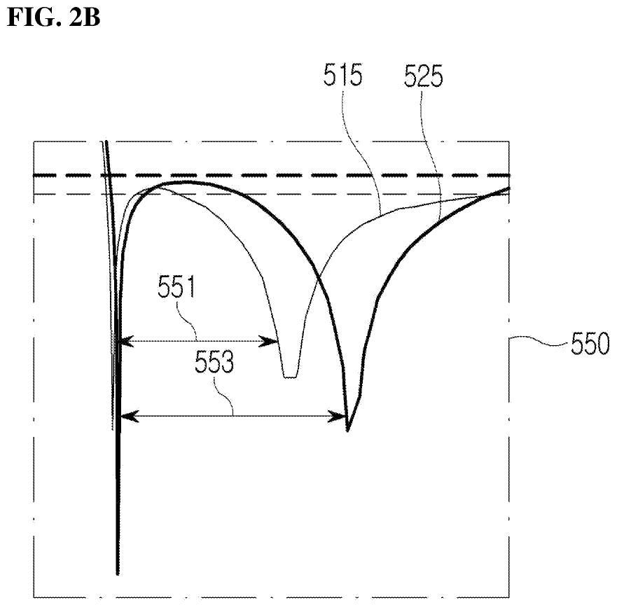

FIG. 2A illustrates a comparative example of the present disclosure and a conventional technology in a doping profile according to a depth (line C-C′ of FIG. 1A) of a side area of the trench 300. FIG. 2B illustrates an enlarged doping profile 550 of the body region of FIG. 2A. The body region where an optimized thermal process of the present disclosure is performed is indicated by a thin line, and the body region to which a process of the conventional art is applied is indicated by a thick line.

Referring to FIG. 2A, a line 510 represents a doping profile before an optimized thermal process proposed by the present disclosure is performed, and a line 515 represents a doping profile after the optimized thermal process proposed by the present disclosure is performed.

In FIG. 2A, a y-direction represents a doping concentration profile, and an x-direction represents the source region, the body region, the drift region, the semiconductor substrate, and the like formed along a depth in a direction from the upper surface of the epitaxial layer 150 to the substrate.

Meanwhile, a line 520 represents a doping profile before a thermal process according to the conventional art is performed, and a line 525 represents a doping profile after the thermal process according to the conventional art is performed.

Referring to the lines 510 and 515 of FIG. 2A, it can be seen that the depth of the drift region is reduced compared to that of the conventional art when the optimized thermal process proposed in the present disclosure is performed.

The slope of the concentration profile of the drift layer 200 of the present disclosure changes rapidly compared to that of the conventional art, and thus, the depth of the drift region is minimized while the depth “A” of the depletion layer and the electric field strength are maintained the same as those of the conventional art, so that the same breakdown voltage can be maintained. In addition, a low on-resistance (Low Rdson) can be obtained by such a reduction of the depth of the drift region.

Referring to the enlarged doping profile 550 of the body region 340 of FIG. 2B, it can be seen that the process conditions are optimized during the body region annealing proposed in the present disclosure, so that the channel length 551 according to the embodiment of the present disclosure is reduced compared to the channel length 553 according to the conventional art. Accordingly, an ultra-short channel semiconductor device, which is a feature of the present disclosure, can be implemented, and low on-resistance can be implemented while minimizing the degradation of the breakdown voltage.

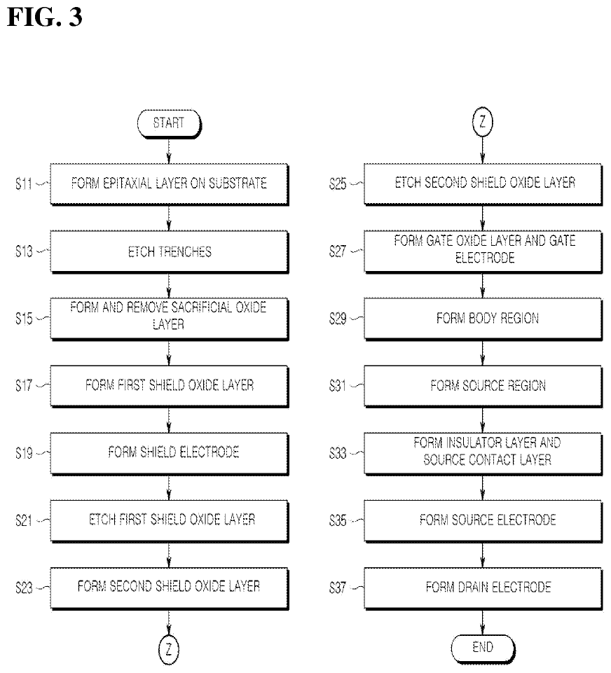

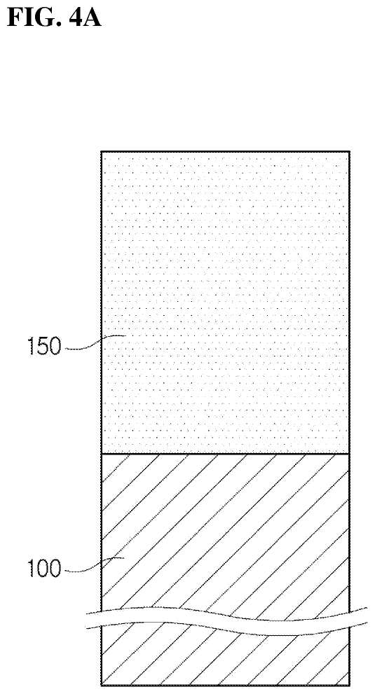

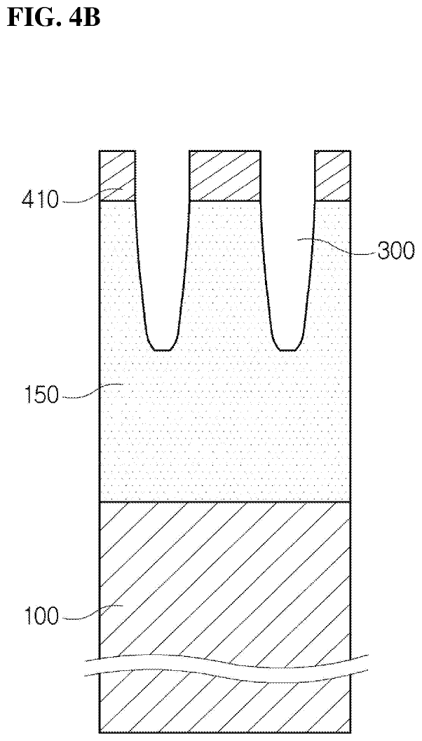

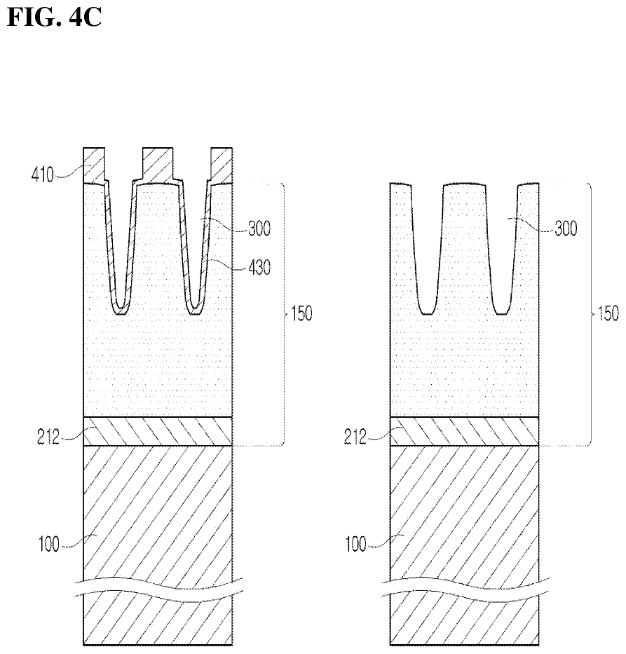

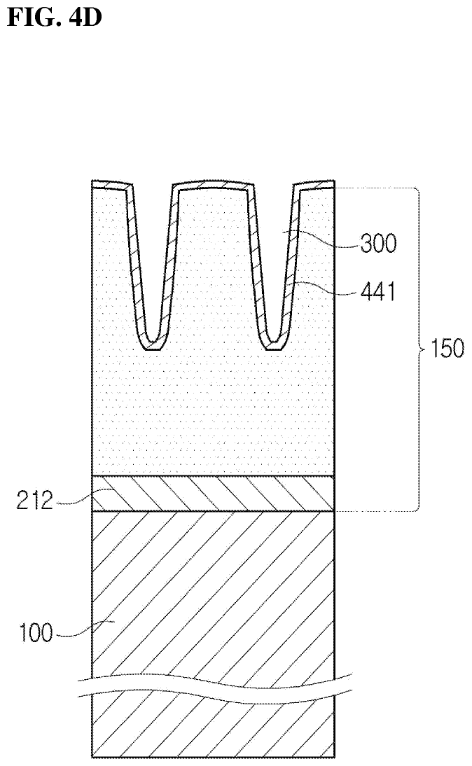

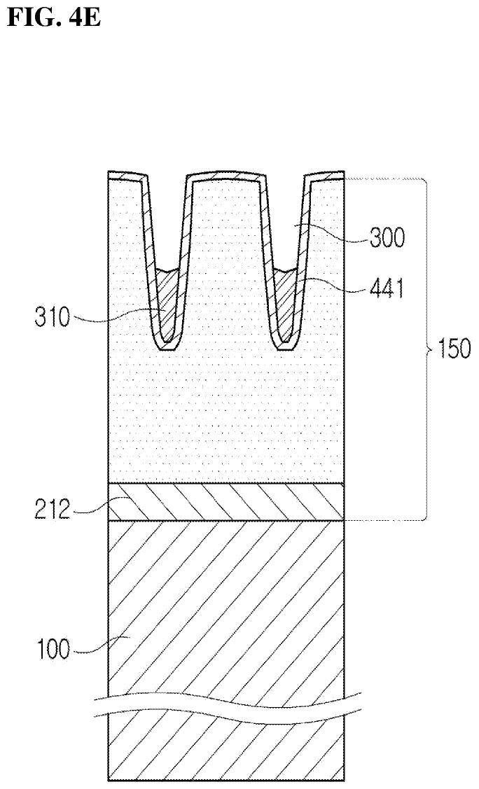

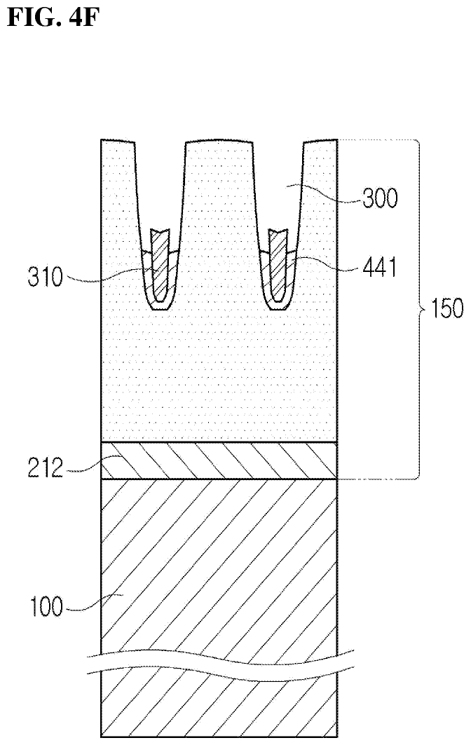

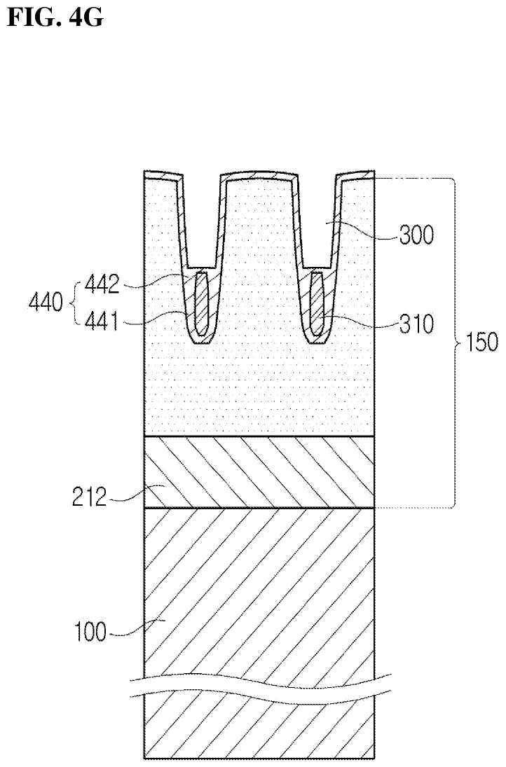

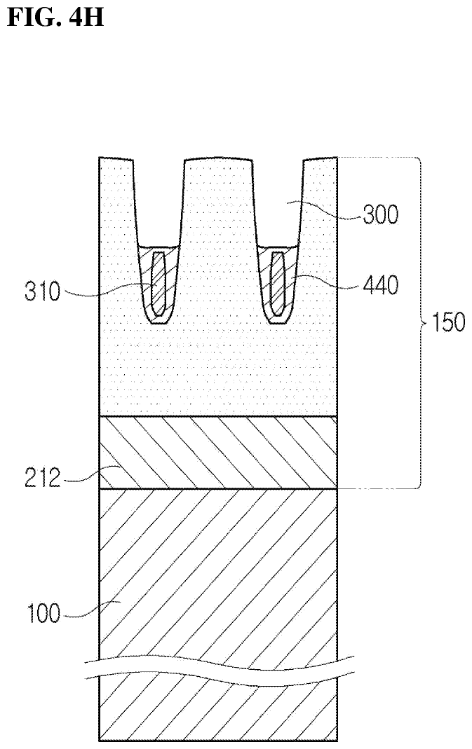

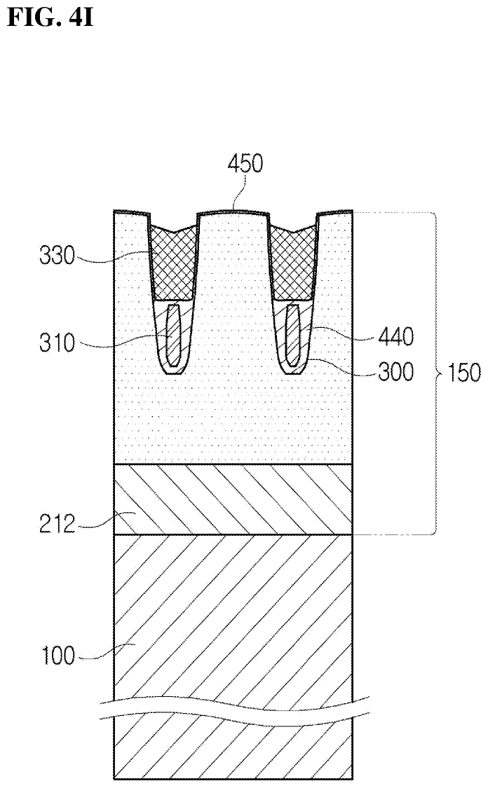

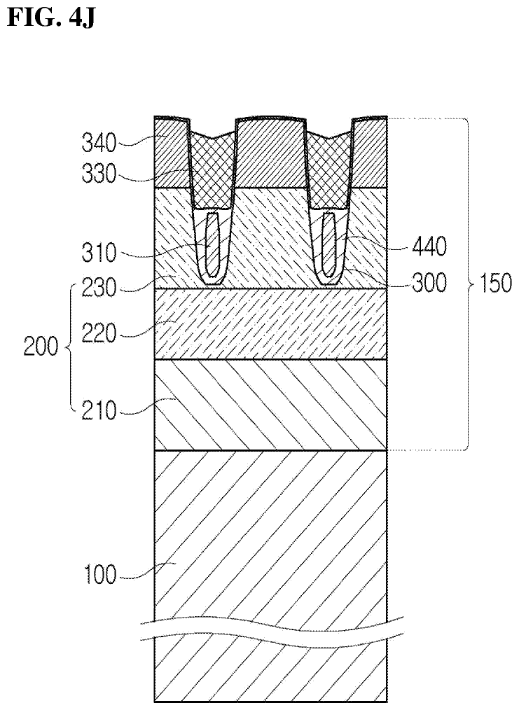

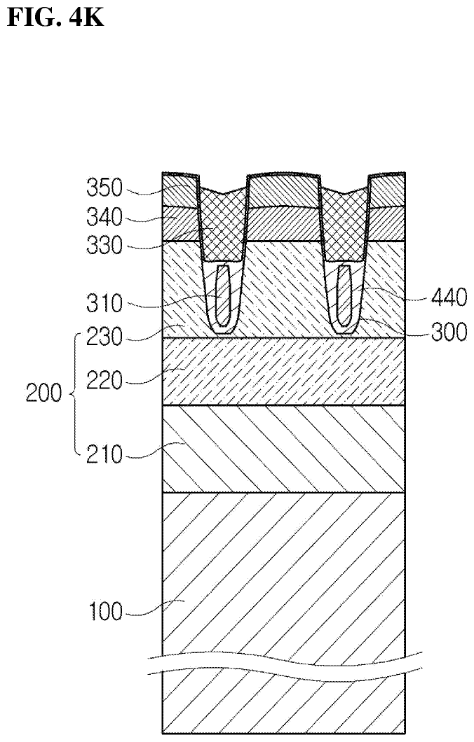

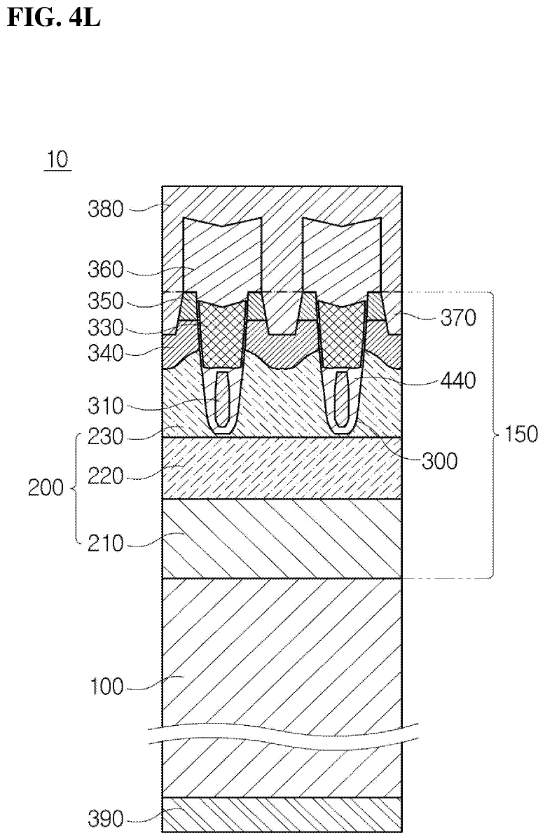

The power semiconductor device shown in FIG. 1A can be manufactured according to the process flowchart of FIG. 3 and on the basis of a manufacturing method or process shown in FIGS. 4A to 4L.

FIG. 3 illustrates a process flowchart for describing a manufacturing method of the semiconductor device proposed by the present disclosure. FIGS. 4A to 4L illustrate views for describing the manufacturing method of the semiconductor device according to one or more embodiments of the present disclosure.

Referring to FIGS. 3 and 4A, in step S11, a manufacturing apparatus for manufacturing the semiconductor device 10 may form the epitaxial layer 150 on the semiconductor substrate 100 through an epitaxial growth process. In an example, when the semiconductor substrate 100 is a first conductive (e.g., N-type) high concentration substrate, the ultra-high concentration first conductive dopant may be distributed on the semiconductor substrate 100. Phosphorous, arsenic, etc., can be used as the first conductive dopant. The semiconductor substrate 100 may be referred to as an ultra-high concentration first conductive substrate.

The semiconductor substrate 100 may have a thickness of about 10 μm to 50 μm.

Referring to FIGS. 3 and 4B, a plurality of trenches 300 may be formed in step S13. In an example, the plurality of trenches 300 may be formed by an etching process.

For an etching process, a hard mask insulation layer 410 may be deposited on the surface of the epitaxial layer 150. After the hard mask insulation layer 410 is deposited, etching with a photoresist mask may be performed on the hard mask insulation layer 410 deposited on a region which is to be etched to form a trench. Then, an etching process for forming the trench may be performed.

In an example, the depth of the plurality of trenches 300 formed may be 0.5 μm to 6 μm, and may be 0.3 to 0.9 times the thickness of the epitaxial layer 150.

Referring to FIGS. 3 and 4C, in step S15, a sacrificial oxide layer 430 may be formed in the trench 300 and then removed. By the process of forming and removing the sacrificial oxide layer 430, the rough surface and foreign substances in the trench 300 generated by the trench etching can be removed. In addition, due to this, the shield oxide layer 440 having a uniform thickness may be formed in a process of forming the shield oxide layer 440 later.

In an example, a high-temperature thermal process is performed so as to form the sacrificial oxide layer 430. As the temperature becomes higher, the first conductive dopant (e.g., phosphorus or arsenic) implanted into the high concentration semiconductor substrate is diffused into the epitaxial layer 150 at a high concentration, so that the width of a depletion region may be reduced, and as a result, it may be difficult to obtain an appropriate breakdown voltage. In order to prevent this phenomenon, the thermal process for forming the sacrificial oxide layer 430 is performed within 50 minutes at a thermal process temperature of 1,100 degrees or less, which is lower than that of the conventional art. In this way, the degradation of the breakdown voltage can be minimized by appropriately reducing the temperature and processing time of the thermal process.

When the sacrificial oxide layer 430 is formed, a portion of the hard mask insulation layer 410 may remain, but may be removed during the process of removing the sacrificial oxide layer 430.

In FIG. 4C, due to the thermal process performed at the time of forming the sacrificial oxide layer 430, the high concentration dopant disposed within the semiconductor substrate 100 may diffuse into the epitaxial layer 150 to form a first high concentration drift region 212.

The first high concentration drift region 212 may be included in the first conductive drift layer 200 in a subsequent process.

Referring to FIGS. 3 and 4D, a first shield oxide layer 441 may be formed in step S17.

Referring to FIGS. 3 and 4E, the shield electrode 310 may be formed on the first shield oxide layer 441 in step S19. In an example, the shield electrode 310 may be formed in the lower portion of the trench 300. The material of the shield electrode 310 may be polysilicon, polycide, metal, or the like. The shield electrode 310 may be connected to the gate electrode 330 or the source electrode 380.

Referring to FIGS. 3 and 4F, a portion of the first shield oxide layer 441 may be removed by etching in step S21. In this case, the first shield oxide layer 441 may be etched to expose a part or all of the upper portion of the shield electrode 310.

Referring to FIGS. 3 and 4G, a second shield oxide layer 442 may be formed in step S23. The second shield oxide layer 442 may be connected to the remaining portion of the first shield oxide layer 441, may entirely surround the shield electrode 310, and may be formed on the inner side of the trench 300 and on the surface of the epitaxial layer 150. Accordingly, a weak structure inside the trench 300 may be removed.

The first and second shield oxide layers 441 and 442 may be formed at a low temperature of 1,000 degrees Celsius or less to minimize diffusion of the first high concentration drift region 212 of the first conductivity type.

After the second shield oxide layer 442 is formed, the first high concentration drift region 212 of the first conductivity type may diffuse toward the surface of the epitaxial layer.

Referring to FIGS. 3 and 4H, an etching process for removing a portion of the second shield oxide layer 442 may be performed in step S25. In an example, the etching process may be performed such that the upper surface of the remaining portion of the second shield oxide layer 442 and the upper surface of the shield electrode 310 are substantially positioned on the same plane.

When the second shield oxide layer 442 is etched, the shield oxide layer 440 in contact with the sidewall of the trench becomes uneven, thereby reducing leakage current, and improving characteristics between the gate and the source. Referring to FIGS. 3 and 4I, the gate oxide layer 450 may be deposited and the gate electrode 330 may be formed in step S27. In an example, the gate electrode 330 may be formed by a deposition process. Polysilicon may be used as a material for the gate electrode. In an example, after the gate electrode material is deposited higher than the surface of the epitaxial layer 150, an etch-back process or a chemical mechanical polishing (CMP) process may be performed to form the gate electrode. In an example, the upper surface of the gate electrode 330 may be formed lower than the upper surface of the epitaxial layer 150. In an example, the gate electrode 330 may be made of various materials such as gate poly, gate polycide, and metal, etc.

Referring to FIGS. 3 and 4J, the body region 340 may be formed in step S29. In order to form the body region 340, a process of implanting a second conductive type dopant between the trench 300 and the trench 300 may be performed, and an annealing process may be performed. The annealing process is performed at low temperatures between 800 and 1,050 degrees Celsius. In an example, rapid thermal processing (RTP) may be performed. The body region 340 may be formed by implanting ions such as boron, which is a second conductive type dopant, multiple times. The process is optimized through heat treatment at an appropriate temperature and multiple ion implantation processes to minimize deep diffusion of the body region 340 into the epitaxial layer 150. Accordingly, it is possible to implement an ultra-short channel and obtain a low on-resistance.

Due to the thermal process applied in the process of forming the body region 340, the first high concentration drift region 210 of the first conductivity type is additionally diffused to form a medium concentration drift layer 220 and a low concentration drift layer 230. The medium concentration drift layer 220 may diffuse to a region below the shield oxide layer 440. Also, the low concentration drift layer 230 of the first conductivity type is formed between the medium concentration drift layer and the body region 340. As a result, a concentration difference occurs between the first conductive high concentration drift layer 210, the medium concentration drift layer 220, and the low concentration drift layer 230 described in FIG. 1A, which is caused by a thermal process applied to the formation of the body region 340.

In an example, in order to realize the low on-resistance, the upper surface of the medium concentration drift layer 220 may be out-diffused into the lower surface of the trench 300 or may partially overlap. Here, the doping concentration of the medium concentration drift layer 220 may be about 1×E17/cm³ to 1×E19/cm³.

Referring to FIGS. 3 and 4K, the source region 350 may be formed in step S31. In an example, the source region 350 may be formed on the body region 340. The channel length (depth “D” of the body region) formed thereby may be less than ½ of the depth “E” from the surface of the epitaxial layer 150 to the lower portion of the gate electrode. In addition, the source region 350 may be formed such that a ratio of the channel length (depth “D” of the body region) to the depth “H” of the trench is 1:2 to 1:30.

Referring to FIGS. 3 and 4L, the insulation layer 360 and the source contact layer 370 may be formed in step S33. In an example, the insulation layer 360 is deposited on the upper surface of the gate electrode 330, and the insulation layer 360 in the region where the source contact layer 370 is to be formed is etched using a photoresist mask. Next, a contact recess etch process is performed to remove the central portion of the body region 340 and the source region 350 between the trench 300 and the trench 300, and the source contact layer 370 may be formed in the removed portion. The source contact layer 370 may be formed by performing an etch-back process and a chemical mechanical planarization (CMP) process after tungsten deposition to planarize the upper surface of the source contact layer.

After the source contact layer 370 is formed, the source electrode 380 is formed on the source contact layer 370. In an example, the source electrode 380 may be formed of aluminum (Al) or other metallic materials. Subsequently, in step S37, the drain electrode 390 may be formed under the semiconductor substrate 100.

In forming the drift layer 200 through diffusion in the manufacturing process of the above-described semiconductor device, the length of the drift layer 200 is prevented from being increased by using an appropriate temperature lower than a conventionally used temperature, an appropriate process time, and method. In addition, since the process can be optimized through heat treatment at an appropriate temperature and multiple ion implantation processes, deep diffusion of the body region into the drift layer 200 can be minimized. Accordingly, the length of the channel may also be minimized.

Through this series of operations, the on-resistance characteristics can be significantly improved compared to the conventional method while maintaining the breakdown voltage as it is.

### Advantageous Effects

According to one or more embodiments of the present disclosure, the method for manufacturing the semiconductor device proposed by the present disclosure may minimize the thickness of the epitaxial layer and optimize the thermal process, so that the epitaxial layer on the ultra-high concentration first conductive semiconductor substrate may minimize outward diffusion while maintaining the same breakdown voltage and improving the resistances of the channel region and the drift region.

In an example, the power semiconductor device proposed in the present disclosure can have a remarkably low on-resistance without a decrease in the breakdown voltage. That is, a trade-off relationship between breakdown voltage and on-resistance of the semiconductor device can be improved.

In an example, by optimizing the thermal process conditions proposed by the present disclosure, the thickness of the epitaxial layer can be reduced compared to that of the conventional art, and the process time can be shortened. As a result, process costs can be reduced.

Advantageous effects that can be obtained from the present disclosure are not limited to the above-mentioned effects. In addition, other effects not mentioned will be clearly understood from the above description by those skilled in the art to which the present disclosure belongs.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a drain electrode;
a first conductive substrate disposed on the drain electrode;
a first conductive epitaxial layer disposed on the first conductive substrate;
a first conductive drift layer formed within the first conductive epitaxial layer;
a plurality of trenches formed in the first conductive epitaxial layer;
a shield electrode formed in a lower portion of each of the plurality of trenches;
a shield oxide layer formed within each of the plurality of trenches and formed to surround the shield electrode;
a gate electrode formed within each of the plurality of trenches and formed on the shield electrode;
a second conductive body region formed on an upper portion comprising a surface of the first conductive epitaxial layer between the plurality of trenches;
a source region formed on the second conductive body region;
an insulation layer formed on the gate electrode;
a source contact layer formed in contact with the source region; and
a source electrode formed on the source contact layer.

2. The semiconductor device of claim 1, wherein a depth of each trench is between 0.5 μm and 6 μm, and
wherein the depth of each trench is 0.3 to 0.9 times a depth of the epitaxial layer.

3. The semiconductor device of claim 1, wherein a top surface of the gate electrode is lower than a top surface of the first conductive epitaxial layer.

4. The semiconductor device of claim 1, wherein a length of the second conductive body region is equal to or less than ½ of a length from an upper surface of the first conductive epitaxial layer to a lower surface of the gate electrode.

5. The semiconductor device of claim 1, wherein a ratio of a maximum width of the second conductive body region to a depth of each trench is 1:2 to 1:20.

6. The semiconductor device of claim 1, wherein the first conductive drift layer comprises:
a first conductive high concentration drift layer formed adjacent to the substrate;
a first conductive medium concentration drift layer formed between the first conductive high concentration drift layer and the shield oxide layer; and
a first conductive low concentration drift layer formed between the first conductive medium concentration drift layer and the second conductive body region.

7. The semiconductor device of claim 6, wherein depths of the first conductive high concentration drift layer, the first conductive medium concentration drift layer, and the first conductive low concentration drift layer are different from each other.

8. The semiconductor device of claim 1, wherein the source contact layer simultaneously contacts the second conductive body region and the source region.

9. The semiconductor device of claim 1, further comprising:
a gate oxide layer formed on a side surface and a lower surface of the gate electrode.

10. The semiconductor device of claim 9, wherein a side surface of the second conductive body region is in contact with the gate oxide layer,
wherein an upper surface of the second conductive body region is in contact with the source contact layer, and
wherein a lower surface of the second conductive body region is disposed lower than the side surface of the second conductive body region.

11. The semiconductor device of claim 6, wherein a doping concentration of the first conductive drift layer gradually decreases from a contact surface with the first conductive substrate to the second conductive body region.

12. The semiconductor device of claim 6, wherein a top surface of the first conductive medium concentration drift layer is out-diffused into a bottom surface of each trench or partially overlaps the bottom surface of each trench.

13. The semiconductor device of claim 1, wherein a ratio of a depth of the second conductive body region to a depth of each trench is 1:2 to 1:30.

14. A semiconductor device manufacturing method, the method comprising:
forming a first conductive epitaxial layer on a first conductive semiconductor substrate;
forming a plurality of trenches in the first conductive epitaxial layer;
forming a sacrificial oxide layer on a surface of the plurality of trenches;
removing the sacrificial oxide layer;
forming a shield oxide layer on surfaces of the plurality of trenches and the first conductive epitaxial layer;
forming a shield electrode in a lower portion of each of the plurality of trenches;
depositing a gate oxide layer on surfaces of the plurality of trenches, the shield oxide layer and the first conductive epitaxial layer;
forming a gate electrode on the shield electrode;
forming a second conductive body region on an upper portion comprising a surface of the first conductive epitaxial layer between the plurality of trenches;
forming a source region on the second conductive body region;
forming an insulation layer on the gate electrode;
forming a source contact layer in contact with the source region;
forming a source electrode on the source contact layer; and
forming a drain electrode under the semiconductor substrate.

15. The semiconductor device manufacturing method of claim 14, wherein a depth of each trench is between 0.5 μm and 6 μm, and
wherein the depth of each trench is 0.3 to 0.9 times a depth of the epitaxial layer.

16. The semiconductor device manufacturing method of claim 14, wherein the forming of the shield oxide layer on a surface of the plurality of trenches comprises performing a thermal process at a temperature of 1,000 degrees Celsius or less.

17. The semiconductor device manufacturing method of claim 14, wherein the forming of the shield oxide layer comprises:
forming a first shield oxide layer on surfaces of the plurality of trenches and the first conductive epitaxial layer;
etching the first shield oxide layer;
forming a second shield oxide layer on surfaces of the plurality of trenches, the shield electrode, and the first conductive epitaxial layer; and
etching the second shield oxide layer.

18. The semiconductor device manufacturing method of claim 17, wherein the etching of the first shield oxide layer comprises etching the first shield oxide layer such that a portion of an upper portion of the shield electrode is exposed, and
wherein the etching of the second shield oxide layer comprises etching the second shield oxide layer so that an upper surface of a remaining portion of the second shield oxide layer and an upper surface of the shield electrode are positioned on a same plane so as to have a same depth from an upper surface of the first conductive epitaxial layer.

19. The semiconductor device manufacturing method of claim 14, wherein the forming of the gate electrode comprises:
depositing a material for the gate electrode higher than the surface of the first conductive epitaxial layer; and
forming a height of the gate electrode lower than a height of the surface of the first conductive epitaxial layer by performing an etch-back process or a chemical mechanical polishing (CMP) process.

20. The semiconductor device manufacturing method of claim 14, wherein the forming of the second conductive body region comprises:
implanting second conductive dopants into the surface of the first conductive epitaxial layer between the plurality of trenches; and
performing an annealing process at temperatures between 800 and 1,050 degrees Celsius by rapid thermal processing (RTP).

21. The semiconductor device manufacturing method of claim 14, wherein the forming of the second conductive body region is performed such that a length of the second conductive body is equal to or less than ½ of a length from an upper surface of the epitaxial layer to a lower surface of the gate electrode.

22. The semiconductor device manufacturing method of claim 14, wherein the forming of the second conductive body region is performed such that a ratio of a maximum width of the second conductive body to a depth of each trench is 1:2 to 1:20.

23. The semiconductor device manufacturing method of claim 14, wherein the forming of the source contact layer comprises:
etching central portions of the source region and the second conductive body region; and
forming the source contact layer in the etched central portions of the source region and the second conductive body region so that the source region and the second conductive body region simultaneously contact the source contact layer.

24. The semiconductor device manufacturing method of claim 14, further comprising:
forming a first conductive drift layer after an annealing process that is performed in the forming of the second conductive body region.

25. The semiconductor device manufacturing method of claim 14, wherein the forming of the sacrificial oxide layer comprises forming a first high concentration drift region on the semiconductor substrate.

26. The semiconductor device manufacturing method of claim 20, further comprising, after an annealing process that is performed in the forming of the second conductive body region,
forming a first conductive high concentration drift layer after the annealing process is performed;
forming a first conductive medium concentration drift layer on the first conductive high concentration drift layer; and
forming a first conductive low concentration drift layer on the first conductive medium concentration drift layer.

27. The semiconductor device manufacturing method of claim 26, wherein a top surface of the first conductive medium concentration drift layer is out-diffused into a bottom surface of each trench or partially overlaps the bottom surface of each trench.

28. The semiconductor device manufacturing method of claim 26, wherein a doping concentration of the first conductive medium concentration drift layer is 1×E17/cm³ to 1×E19/cm³.

29. The semiconductor device manufacturing method of claim 18, wherein the shield oxide layer becomes uneven after the etching of the second shield oxide layer is performed.
